(19) United States
(12) Patent Application Publication
(10) Pub. No.: US 2016/0348269 A1
(43) Pub. Date: Dec. 1, 2016

(54) METHOD FOR MANUFACTURING METAL NANO-WIRE

(71) Applicant: NATIONAL CHENG KUNG UNIVERSITY, TAINAN CITY (TW)

(72) Inventors: Chau-Nan HONG, TAINAN CITY (TW); Cyun-Jhe YAN, TAINAN CITY (TW)

(21) Appl. No.: 14/864,902

(22) Filed: Sep. 25, 2015

(30) Foreign Application Priority Data
May 29, 2015 (TW) 104117477

(51) Int. Cl. C30B 7/14; C30B 29/02; C30B 29/62; C30B 30/00

(52) U.S. Cl. CPC C30B 7/14; C30B 30/00; C30B 29/02; C30B 29/62

(57) ABSTRACT

A method for manufacturing metal nano-wires is described, which is suitable for manufacturing silver nano-wires and copper nano-wires and includes the following steps. A metal nano-particle resulting solution is prepared to mix a first metal ionic compound, a first reductant and a first capping agent, so as to form various metal nano-particles. An illumination treatment is performed on the metal nano-particle resulting solution. A portion of the metal nano-particle resulting solution after the illumination treatment is mixed with a metal nano-wire resulting solution to form metal nano-wires by using the metal nano-particles of the portion of the metal nano-particle resulting solution as seeds. The metal nano-wire resulting solution includes a second metal ionic compound, a second reductant and a second capping agent.

### RELATED APPLICATIONS

This application claims priority to Taiwan Application Ser. No. 104117477, filed May 29, 2015, which is herein incorporated by reference.

### BACKGROUND

1. Field of Invention

The present invention relates to a method for manufacturing nano-wires. More particularly, the present invention relates to a method for manufacturing metal nano-wires, silver nano-wires and copper nano-wires especially.

2. Description of Related Art

Conventionally, in the manufacturing of a metal nano-wire solution, such as a silver nano-wire solution or a copper nano-wire solution, by using a batch method, important process parameters, such as reaction time, a reaction temperature, the quantity of an additive, the quantity of a capping agent, the quantity of a metal precursor and the quantity of a reductant, affect a length to width ratio of metal nano-wires. However, the most important parameter for a clean metal nano-wire solution is a ratio of the quantity of the metal precursor to the quantity of the capping agent. The ratio needs to be constant during the process, otherwise metal nano-particles are formed, and thus the difficulty of a subsequent purifying operation of the metal nano-wires is increased. In the batch method, the metal precursor is consumed over time, such that the ratio of the quantity of the metal precursor in the solution is inconstant. As a result, the metal nano-particles are formed, and the purity of the metal nano-wires is poor.

Currently, in order to solve the problem of the growing of the metal nano-particles, two typical methods including a batch seed-assisted growth method and a continuous process method are developed. In the batch seed-assisted growth method, metal nano-particles grown beforehand are taken out and put in a fresh growth solution, such that the metal nano-particles can be used as seeds of metal nano-wires to grow the metal nano-wires in an appropriate condition. However, the method still has the problem of too many metal nano-particles existing in the metal nano-wire solution, and a complex purification operation is needed to obtain the metal nano-wire solution of high purity.

In addition, the continuous process method is performed by strictly controlling a ratio of the quantity of the metal precursor to the quantity of the capping agent in a certain range, so as to grow metal nano-wires of high purity. However, the method has disadvantages of difficult operation, complex purification and strict process conditions.

### SUMMARY

Therefore, one objective of the present invention is to provide a method for manufacturing metal nano-wires, in which metal nano-particles are firstly formed and are used as seeds for growing metal nano-wires sequentially, and an illumination treatment is performed on the metal nano-particles, so as to prompt the metal nano-particles to grow into metal nano-wires, each of which has a one-dimensional structure, in process conditions for growing the metal nano-wires. Thus, the desired metal nano-wires can be successfully formed.

Another objective of the present invention is to provide a method for manufacturing metal nano-wires, in which a solution containing metal nano-particles used as seeds is properly stored to restrain the metal nano-particles in the solution from growing into metal nano-wires, so as to prevent the metal nano-particles and the metal nano-wires from coexisting in the solution. The method further includes performing an illumination treatment on the metal nano-particles used as the seeds to prompt the metal nano-particles to grow into the metal nano-wires. Thus, purity of a metal nano-wire solution is effectively enhanced, thereby greatly reducing difficulty of purifying the metal nano-wires.

According to the aforementioned objectives, the present invention provides a method for manufacturing metal nano-wires, which is suitable to manufacture silver nano-wires and copper nano-wires. In the method for manufacturing the metal nano-wires, a metal nano-particle resulting solution is prepared. The operation of preparing the metal nano-particle resulting solution includes mixing a first metal ionic compound, a first reductant and a first capping agent to form various metal nano-particles. An illumination treatment is performed on the metal nano-particle resulting solution. A portion of the metal nano-particle resulting solution after the illumination treatment is mixed with a metal nano-wire resulting solution to form various metal nano-wires by using the metal nano-particles of the portion of the metal nano-particle resulting solution as seeds. The metal nano-wire resulting solution includes a second metal ionic compound, a second reductant and a second capping agent, and the second metal ionic compound, the second reductant and the second capping agent are respectively identical to the first metal ionic compound, the first reductant and the first capping agent.

According to one embodiment of the present invention, each of the first metal ionic compound and the second metal ionic compound includes at least one silver ionic compound, each of the first capping agent and the second capping agent is polyvinylpyrrolidone (PVP), and each of the first reductant and the second reductant is ethylene glycol, 1,2-propylene glycol or 1,3-propylene glycol.

According to one embodiment of the present invention, the operation of preparing the metal nano-particle resulting solution further includes mixing a salt additive.

According to one embodiment of the present invention, the salt additive includes at least one chlorine-containing compound.

According to one embodiment of the present invention, the operation of preparing the metal nano-particle resulting solution includes the following operations. The salt additive and the first capping agent are mixed with the first reductant to form a mixed solution. The mixed solution is put in an opaque locking bottle. A pre-heating treatment is performed on the mixed solution in the opaque locking bottle to heat the mixed solution to a synthesis temperature. The first metal ionic compound is added into the mixed solution at the synthesis temperature to form the metal nano-particles.

According to one embodiment of the present invention, the operation of mixing the salt additive and the first capping agent with the first reductant further includes controlling a mixing temperature ranging from 10 degrees centigrade to 50 degrees centigrade.

According to one embodiment of the present invention, the synthesis temperature ranges from 70 degrees centigrade to 170 degrees centigrade.

According to one embodiment of the present invention, a molecular weight of the polyvinylpyrrolidone ranges from 30000 to 360000.

According to one embodiment of the present invention, the operation of mixing the portion of the metal nano-particle resulting solution with the metal nano-wire resulting solution includes the following operations. The portion of the metal nano-particle resulting solution and the second capping agent are mixed with the second reductant to form a mixed solution. The mixed solution is put in an opaque locking bottle. A pre-heating treatment is performed on the mixed solution in the opaque locking bottle to heat the mixed solution to a synthesis temperature. The second metal ionic compound is added into the mixed solution at the synthesis temperature to form the metal nano-wires by using the metal nano-particles as the seeds.

According to one embodiment of the present invention, the operation of mixing the portion of the metal nano-particle resulting solution and the second capping agent with the second reductant further includes controlling a mixing temperature ranging from 10 degrees centigrade to 50 degrees centigrade.

According to one embodiment of the present invention, the synthesis temperature ranges from 70 degrees centigrade to 170 degrees centigrade.

According to one embodiment of the present invention, each of the first metal ionic compound and the second metal ionic compound includes at least one copper ionic compound, each of the first capping agent and the second capping agent is an amine compound, and each of the first reductant and the second reductant is an aldehyde compound.

According to one embodiment of the present invention, the amine compound is hexamethylene diamine, and the aldehyde compound is carbohydrate, vitamin C or hydrazine.

According to one embodiment of the present invention, the operation of preparing the metal nano-particle resulting solution includes the following operations. The first metal ionic compound and the first capping agent are mixed to form a mixed solution using a solvent, in which the solvent is distilled water. The mixed solution is put in an opaque locking bottle. A pre-heating treatment is performed on the mixed solution in the opaque locking bottle. The first reductant is added into the mixed solution, and the mixed solution is heated to a synthesis temperature to form the metal nano-particles.

According to one embodiment of the present invention, the operation of mixing the first metal ionic compound and the first capping agent using the solvent further includes controlling a mixing temperature ranging from 10 degrees centigrade to 50 degrees centigrade.

According to one embodiment of the present invention, the synthesis temperature ranges from 70 degrees centigrade to 170 degrees centigrade.

According to one embodiment of the present invention, the operation of mixing the portion of the metal nano-particle resulting solution with the metal nano-wire resulting solution includes the following operations. The second metal ionic compound and the second capping agent are mixed to form a mixed solution using a solvent, in which the solvent is distilled water. The mixed solution is put in an opaque locking bottle. The portion of the metal nano-particle resulting solution is added into the mixed solution. A pre-heating treatment is performed on the mixed solution in the opaque locking bottle. The second reductant is added into the mixed solution, and the mixed solution is heated to a synthesis temperature to form the metal nano-wires by using the metal nano-particles as the seeds.

According to one embodiment of the present invention, the operation of mixing the second metal ionic compound and the second capping agent using the solvent further includes controlling a mixing temperature ranging from 10 degrees centigrade to 50 degrees centigrade.

According to one embodiment of the present invention, the synthesis temperature ranges from 70 degrees centigrade to 170 degrees centigrade.

According to one embodiment of the present invention, between the operation of preparing the metal nano-particle resulting solution and the operation of performing the illumination treatment, the method further includes storing the metal nano-particle resulting solution in an opaque environment with a storage temperature, in which the storage temperature ranges from −20 degrees centigrade to 60 degrees centigrade.

According to one embodiment of the present invention, the operation of performing the illumination treatment includes using a light source, and the light source has a wavelength ranging from 325 nm to 800 nm.

According to one embodiment of the present invention, after the operation of mixing the portion of the metal nano-particle resulting solution with the metal nano-wire resulting solution, the method further includes the following operations. A first rinsing treatment is performed on the metal nano-wires using acetone. A second rinsing treatment is performed on the metal nano-wires using distilled water. The metal nano-wires are stored in distilled water.

### BRIEF DESCRIPTION OF THE DRAWINGS

The invention can be more fully understood by reading the following detailed description of the embodiment, with reference made to the accompanying drawings as follows:

FIG. 1 is a flow chart of a method for manufacturing metal nano-wires in accordance with one embodiment of this invention.

### DETAILED DESCRIPTION

In view of when metal nano-wires are formed by a batch technique in the prior art, purity of a metal nano-wire solution is lower, a purifying process is complex, and process conditions are strict. Thus, the present disclosure provides a method for manufacturing metal nano-wires, which is suitable to manufacture silver nano-wires and copper nano-wires. In the present invention, an illumination treatment is performed on metal nano-particles used as seeds to prompt the metal nano-particles to grow into metal nano-wires each of which has a one-dimensional structure sequentially. In addition, the present invention properly stores the metal nano-particles with suitable conditions. Thus, a metal nano-wire solution with high purity can be obtained, such that difficulty of a subsequent purifying process is greatly reduced, and even the subsequent purifying process is omitted. Therefore, the method for manufacturing the metal nano-wires of the present invention has advantages including an operation is easy, a process is simple and the metal nano-wire solution has high purity.

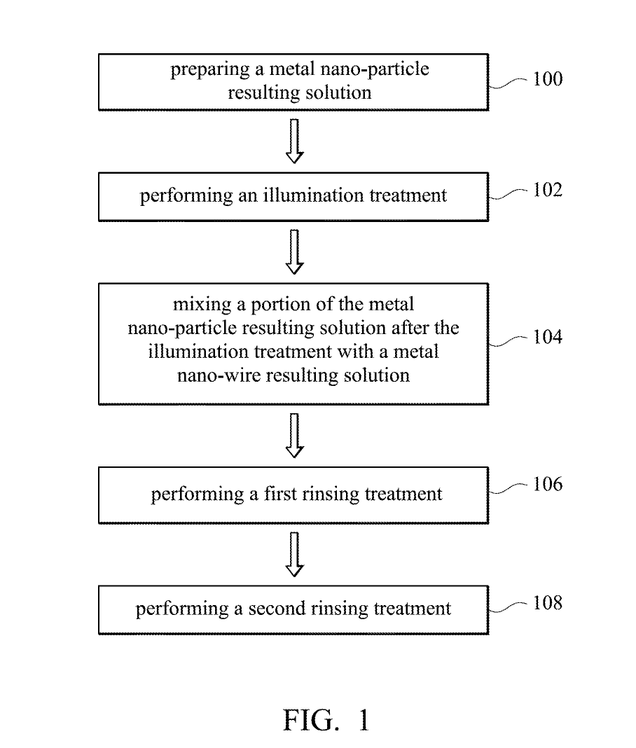

Refer to FIG. 1. FIG. 1 is a flow chart of a method for manufacturing metal nano-wires in accordance with one embodiment of this invention. The method for manufacturing the metal nano-wires may be suitable to manufacture silver nano-wires and copper nano-wires. In the present embodiment, the metal nano-wires are manufactured by using a batch method. In some examples, in the fabrication of the metal nano-wires, an operation 100 is performed to prepare a metal nano-particle resulting solution. In the operation of preparing the metal nano-particle resulting solution, a first metal ionic compound, a first reductant and a first capping agent may be mixed. After the first metal ionic compound, the first reductant and the first capping agent are mixed with each other, the metal nano-particle resulting solution having various metal nano-particles can be formed. In the subsequent process, the metal nano-particles can be used as seeds for growing metal nano-wires. In some exemplary examples, the metal nano-particle resulting solution further includes a salt additive.

In some examples, after the operation of preparing the metal nano-particle resulting solution is completed, the metal nano-particle resulting solution may be optionally stored in a proper condition according to process requirements, so as to prevent the reaction from continuing to grow the metal nano-particles into the metal nano-wires. For example, the metal nano-particle resulting solution may be stored in an opaque environment with a storage temperature ranging from −20 degrees centigrade to 60 degrees centigrade.

Next, an operation 102 is performed to perform an illumination treatment on the metal nano-particle resulting solution. With the illumination treatment, the metal nano-particles are promoted to respectively grow into one-dimensional structures, i.e. metal nano-wire structures, during subsequent growing of metal nano-wires. In some examples, the operation of performing the illumination treatment includes using a light source, and the light source may have a wavelength ranging from 325 nm to 800 nm.

After the illumination treatment is completed, an operation 104 may be performed, in which a portion of the metal nano-particle resulting solution after the illumination treatment is taken out, and the portion of the metal nano-particle resulting solution is mixed with a metal nano-wire resulting solution. In the operation of mixing the metal nano-particle resulting solution and the metal nano-wire resulting solution, the metal nano-particles in the metal nano-particle resulting solution can be used as growth seeds, and the metal nano-particles after being treated by illuminating tend to grow into one-dimensional structures, thus various metal nano-wires can successfully grow by using the metal nano-particles as bases. In some exemplary examples, the metal nano-wires, each of which has a line diameter ranging from 50 nm to 200 nm and a length to width ratio ranging from 40 to 500, can be obtained. In addition, in the mixed solution, a quantity ratio of the metal nano-particles to the metal nano-wires ranges from 0 to 4.

In some examples, the metal nano-wire resulting solution includes a second metal ionic compound, a second reductant and a second capping agent. In addition, the second metal ionic compound, the second reductant and the second capping agent of the metal nano-wire resulting solution may be respectively identical to the first metal ionic compound, the first reductant and the first capping agent, for example. In some exemplary examples, the metal nano-wire resulting solution further includes a salt additive. The salt additive may be identical to the salt additive of the metal nano-particle resulting solution, or may be different from the salt additive of the metal nano-particle resulting solution.

In some examples, after the operation of mixing the portion of the metal nano-particle resulting solution and the metal nano-wire resulting solution is completed, an operation 106 may be further optionally performed, in which a rinsing treatment is performed on the metal nano-wires using acetone to remove impurities on the metal nano-wires, such as the residual reductant. In some certain examples, an operation 108 may be optionally performed, in which a rinsing treatment is performed on the metal nano-wires using distilled water. After the rinsing of the metal nano-wires is completed, the metal nano-wires may be stored in the distilled water.

Some examples are used to illustrate the applications of the aforementioned embodiment on the manufacturing of silver nano-wires and copper nano-wires. In some examples, the method is applied to manufacture the silver nano-wires. A silver nano-particle resulting solution is firstly prepared, in which the silver nano-particle resulting solution includes a silver ionic compound (i.e. a silver precursor), a reductant and a capping agent. The silver nano-particle resulting solution includes at least one silver ionic compound. The silver ionic compound may be, for example, silver nitrate (AgNO₃). The reductant may be ethylene glycol, 1,2-propylene glycol or 1,3-propylene glycol, for example. The capping agent may be, for example, polyvinylpyrrolidone (PVP).

The inventors of the present application find that in the process of manufacturing the silver nano-wires, purity of the silver nano-wires in the solution is affected while the polyvinylpyrrolidone capping agents with different molecular weights are used. For example, polyvinylpyrrolidone with a less molecular weight tends to synthesize silver nano-particles and silver nano-wires with a lower length to width ratio, while polyvinylpyrrolidone with a greater molecular weight tends to synthesize silver nano-wires with a higher length to width ratio. Thus, in some examples, the molecular weight of polyvinylpyrrolidone ranges from 30000 to 360000.

In the examples, the operation of preparing the silver nano-particle resulting solution may optionally include mixing a salt additive, such as a group WA compound, in addition to mixing the silver ionic compound, the reductant and the capping agent. In some examples, the salt additive includes at least one chlorine-containing compound. In some exemplary examples, the salt additive includes sodium chloride (NaCl), potassium chloride (KCI), sodium bromide (NaBr) and/or potassium bromide (KBr).

In the examples, the operation of preparing the silver nano-particle resulting solution includes mixing the salt additive and the capping agent with the reductant to form a mixed solution. In some exemplary examples, the operation of mixing the salt additive and the capping agent with the reductant includes controlling a mixing temperature ranging from 10 degrees centigrade to 50 degrees centigrade. Next, the mixed solution may be put in an opaque locking bottle. A pre-heating treatment is performed on the mixed solution in the opaque locking bottle to heat the mixed solution to a synthesis temperature. The synthesis temperature is a reaction temperature of growing the silver nano-particles, and the synthesis temperature may, for example, range from 70 degrees centigrade to 170 degrees centigrade. At the synthesis temperature, the silver ionic compound is added into the mixed solution, such that the silver nano-particles are formed. After the synthesizing of the silver nano-particles is completed, the silver nano-particles are preferably stored in an opaque environment with a storage temperature ranging from −20 degrees centigrade to 60 degrees centigrade, to prevent the silver nano-particles from continuously reacting and growing into silver nano-wires.

Then, an illumination treatment is performed on the silver nano-particle resulting solution. With the illumination treatment, the silver nano-particles can be promoted to respectively grow into one-dimensional nano-wire structures during subsequent growing of the silver nano-wires. In some exemplary examples, a light source used in the illumination treatment may have a wavelength ranging from 325 nm to 800 nm.

Subsequently, a portion of the silver nano-particle resulting solution after the illumination treatment is taken out, and the portion of the silver nano-particle resulting solution is mixed with a silver nano-wire resulting solution, such that the silver nano-wires can successfully grow by using the silver nano-particles after being treated by illuminating as seeds. In some exemplary examples, the silver nano-wires, each of which has a line diameter ranging from 50 nm to 200 nm and a length to width ratio ranging from 40 to 500, can be obtained, and a quantity ratio of the silver nano-particles to the silver nano-wires ranges from 0 to 4. The silver nano-wire resulting solution may include a silver metal ionic compound, a reductant and a capping agent, which may be respectively identical to the silver ionic compound, the reductant and the capping agent of the silver nano-particle resulting solution, for example. In some exemplary examples, the silver nano-wire resulting solution further includes a salt additive, in which the salt additive may be identical to the salt additive of the silver nano-particle resulting solution, or may be different from the salt additive of the silver nano-particle resulting solution.

In some exemplary examples, in the operation of mixing the portion of the silver nano-particle resulting solution and the silver nano-wire resulting solution, the silver nano-particle resulting solution and the capping agent are mixed with the reductant to form a mixed solution. A mix temperature may be controlled at a range from 10 degrees centigrade to 50 degrees centigrade. Next, the mixed solution may be put in an opaque locking bottle. A pre-heating treatment is performed on the mixed solution in the opaque locking bottle to heat the mixed solution to a synthesis temperature. The synthesis temperature is a reaction temperature of growing the silver nano-wires, and the synthesis temperature may, for example, range from 70 degrees centigrade to 170 degrees centigrade. At the synthesis temperature, the silver ionic compound is added into the mixed solution, such that the silver nano-wires are formed by using the silver nano-particles as seeds. Subsequently, a rinsing treatment is performed on the silver nano-wires using acetone to remove impurities on the silver nano-wires, such as the residual reductant. The silver nano-wires are stored in distilled water.

In some exemplary examples, in the process of manufacturing silver nano-wires, a silver nano-particle resulting solution is firstly prepared. 0.004 g of sodium chloride and 0.4 g of polyvinylpyrrolidone with a molecular weight of 360000 are mixed with ethylene glycol. The mixed solution is put in an opaque locking bottle. Then, the mixed solution is preheated at a temperature of 160 degrees centigrade by using an oven. After a temperature of the mixed solution is raised to 160 degrees centigrade, 0.25 g of silver nitrate powder is directly added into the mixed solution. Subsequently, the mixed solution is cooled and stored at a temperature of 60 degrees centigrade.

Next, an illumination treatment is performed on the silver nano-particle resulting solution, in which white light with a luminous intensity of 20 mW/cm² is used to perform the illumination treatment for 60 minutes at 60 degrees centigrade.

Subsequently, 5 mL of the silver nano-particle resulting solution after the illumination treatment is taken out, and the silver nano-particle resulting solution after the illumination treatment and 0.4 g of polyvinylpyrrolidone with a molecular weight of 360000 are mixed with 60 mL of ethylene glycol. The mixed solution is put in an opaque locking bottle. The mixed solution is preheated at a proper oven temperature, such as 160 degrees centigrade. After a temperature of the mixed solution is raised to a predetermined temperature, such as 160 degrees centigrade, 0.25 g of a silver nitrate powder is directly added into the mixed solution. High purity silver nano-wires can be formed at a proper reaction temperature for a proper reaction duration, such as at 160 degrees centigrade for 30 minutes. Subsequently, acetone is used to rinse to remove impurities, such as the residual reductant, and then the silver nano-wires are stored in distilled water.

In some examples, the method is applied to manufacture the copper nano-wires. A copper nano-particle resulting solution is firstly prepared, in which the copper nano-particle resulting solution includes a copper ionic compound (i.e. a copper precursor), a reductant and a capping agent. The copper nano-particle resulting solution includes at least one copper ionic compound. The copper ionic compound may be, for example, copper chloride (CuCl₂). The reductant may be aldehyde compound, such as carbohydrate, vitamin C or hydrazine. The capping agent may be an amine compound, such as hexamethylene diamine.

In the examples, the operation of preparing the copper nano-particle resulting solution includes mixing the copper ionic compound and the capping agent by using a solvent to form a mixed solution, in which the solvent may be distilled water. In some exemplary examples, the operation of mixing the copper ionic compound and the capping agent using the solvent includes controlling a mixing temperature ranging from 10 degrees centigrade to 50 degrees centigrade. Next, the mixed solution may be put in an opaque locking bottle. A pre-heating treatment is performed on the mixed solution in the opaque locking bottle. Then, the reductant is added into the mixed solution, and the mixed solution is heated to a synthesis temperature, such that copper nano-particles can be formed. The synthesis temperature is a reaction temperature of growing the copper nano-particles, and the synthesis temperature may, for example, range from 70 degrees centigrade to 170 degrees centigrade. After the synthesizing of the copper nano-particles is completed, the copper nano-particles are preferably stored in an opaque environment with a storage temperature ranging from −20 degrees centigrade to 60 degrees centigrade, to prevent the copper nano-particles from continuously reacting and growing into copper nano-wires.

Then, an illumination treatment is performed on the copper nano-particle resulting solution. With the illumination treatment, the copper nano-particles can be promoted to respectively grow into one-dimensional nano-wire structures during subsequent growing of the copper nano-wires. In some exemplary examples, a light source used in the illumination treatment may have a wavelength ranging from 325 nm to 800 nm.

Subsequently, a portion of the copper nano-particle resulting solution after the illumination treatment is taken out, and the portion of the copper nano-particle resulting solution is mixed with a copper nano-wire resulting solution, such that the copper nano-wires can successfully grow by using the copper nano-particles after being treated by illuminating as seeds. In some exemplary examples, the copper nano-wires, each of which has a line diameter ranging from 50 nm to 300 nm and a length to width ratio ranging from 40 to 500, can be obtained, and a quantity ratio of the copper nano-particles to the copper nano-wires ranges from 0 to 4. The copper nano-wire resulting solution may include a copper metal ionic compound, a reductant and a capping agent, which may be respectively identical to the copper ionic compound, the reductant and the capping agent of the copper nano-particle resulting solution, for example.

In some exemplary examples, in the operation of mixing the portion of the copper nano-particle resulting solution and the copper nano-wire resulting solution, the copper ionic compound and the capping agent are firstly mixed by using a solvent to form a mixed solution, in which the solvent may be distilled water similarly. A mix temperature may be controlled at a range from 10 degrees centigrade to 50 degrees centigrade. Next, the mixed solution may be put in an opaque locking bottle. The copper nano-particle resulting solution is added into the mixed solution. A pre-heating treatment is performed on the mixed solution in the opaque locking bottle. Then, the reductant is added into the mixed solution, and the mixed solution is heated to a synthesis temperature, such that the copper nano-wires are formed by using the copper nano-particles as seeds. The synthesis temperature is a reaction temperature of growing the copper nano-wires, and the synthesis temperature may, for example, range from 70 degrees centigrade to 170 degrees centigrade. Subsequently, a rinsing treatment is performed on the copper nano-wires using acetone to remove impurities on the copper nano-wires, such as the residual reductant. In addition, a rinsing treatment may be optionally performed on the copper nano-wires using distilled water. Then, the copper nano-wires are stored in distilled water.

In some exemplary examples, in the process of manufacturing copper nano-wires, a copper nano-particle resulting solution is firstly prepared. 0.63 g of copper chloride and 3.78 g of hexamethylene diamine are mixed by using distilled water. The mixed solution is put in an opaque locking bottle. Then, the mixed solution is rotated, stirred and preheated at 50 degrees centigrade by using a heating plate with a rotation speed of 120 rpm. Next, 1.05 g of sucrose is directly added to the mixed solution. After being mixed uniformly, the mixed solution is put in an oven with a heating temperature of 103 degrees centigrade and is heated for 2 hours, such that copper nano-particles are grown. Subsequently, the mixed solution is cooled and stored at a temperature of 60 degrees centigrade.

Next, an illumination treatment is performed on the copper nano-particle resulting solution, in which white light with a luminous intensity of 20 mW/cm² is used to perform the illumination treatment for 60 minutes at 60 degrees centigrade.

Subsequently, 0.63 g of copper chloride and 3.78 g of hexamethylene diamine are dissolve in 210 mL of distilled water. The mixed solution is put in an opaque locking bottle. Then, 21 mL of the copper nano-particle resulting solution after the illumination treatment is added to the mixed solution. Next, the mixed solution is rotated, stirred and preheated at 50 degrees centigrade by using a heating plate with a rotation speed of 120 rpm. Subsequently, 1.05 g of sucrose is directly added to the mixed solution. After being mixed uniformly, the mixed solution is put in an oven with a heating temperature of 103 degrees centigrade and is heated for 12 hours, such that copper nano-wires of high purity are obtained. Subsequently, acetone and distilled water are used to rinse to remove impurities, such as the residual reductant, and then the copper nano-wires are stored in distilled water.

According to the aforementioned embodiments, one advantage of the present invention is that in a method for manufacturing metal nano-wires of the present invention, metal nano-particles are firstly formed and are used as seeds for growing metal nano-wires sequentially, and an illumination treatment is performed on the metal nano-particles, so as to prompt the metal nano-particles to grow into metal nano-wires, each of which has a one-dimensional structure, in process conditions for growing the metal nano-wires. Thus, the desired metal nano-wires can be successfully formed.

According to the aforementioned embodiments, another advantage of the present invention is that in a method for manufacturing metal nano-wires of the present invention, a solution containing metal nano-particles used as seeds is properly stored to restrain the metal nano-particles in the solution from growing into metal nano-wires, so as to prevent the metal nano-particles and the metal nano-wires from coexisting in the solution. The method further includes performing an illumination treatment on the metal nano-particles used as the seeds to prompt the metal nano-particles to grow into the metal nano-wires. Thus, purity of a metal nano-wire solution is effectively enhanced, thereby greatly reducing difficulty of purifying the metal nano-wires.

Although the present invention has been described in considerable detail with reference to certain embodiments thereof, the foregoing embodiments of the present invention are illustrative of the present invention rather than limiting of the present invention. It will be apparent to those having ordinary skill in the art that various modifications and variations can be made to the present invention without departing from the scope or spirit of the invention. Therefore, the spirit and scope of the appended claims should not be limited to the description of the embodiments contained herein.

What is claimed is:

1. A method for manufacturing metal nano-wires, which is suitable to manufacture a plurality of silver nano-wires and a plurality of copper nano-wires, and the method comprising:
preparing a metal nano-particle resulting solution, wherein the operation of preparing the metal nano-particle resulting solution comprises mixing a first metal ionic compound, a first reductant and a first capping agent to form a plurality of metal nano-particles;
performing an illumination treatment on the metal nano-particle resulting solution; and
mixing a portion of the metal nano-particle resulting solution after the illumination treatment with a metal nano-wire resulting solution to form a plurality of metal nano-wires by using the metal nano-particles of the portion of the metal nano-particle resulting solution as seeds, wherein the metal nano-wire resulting solution comprises a second metal ionic compound, a second reductant and a second capping agent, and the second metal ionic compound, the second reductant and the second capping agent are respectively identical to the first metal ionic compound, the first reductant and the first capping agent.

2. The method of claim 1, wherein
each of the first metal ionic compound and the second metal ionic compound comprises at least one silver ionic compound;
each of the first capping agent and the second capping agent is polyvinylpyrrolidone (PVP); and
each of the first reductant and the second reductant is ethylene glycol, 1,2-propylene glycol or 1,3-propylene glycol.

3. The method of claim 2, wherein the operation of preparing the metal nano-particle resulting solution further comprises mixing a salt additive.

4. The method of claim 3, wherein the salt additive comprises at least one chlorine-containing compound.

5. The method of claim 3, wherein the operation of preparing the metal nano-particle resulting solution comprises:
mixing the salt additive and the first capping agent with the first reductant to form a mixed solution;
putting the mixed solution in an opaque locking bottle;
performing a pre-heating treatment on the mixed solution in the opaque locking bottle to heat the mixed solution to a synthesis temperature; and
adding the first metal ionic compound into the mixed solution at the synthesis temperature to form the metal nano-particles.

6. The method of claim 5, wherein the operation of mixing the salt additive and the first capping agent with the first reductant further comprises controlling a mixing temperature ranging from 10 degrees centigrade to 50 degrees centigrade.

7. The method of claim 5, wherein the synthesis temperature ranges from 70 degrees centigrade to 170 degrees centigrade.

8. The method of claim 2, wherein a molecular weight of the polyvinylpyrrolidone ranges from 30000 to 360000.

9. The method of claim 2, wherein the operation of mixing the portion of the metal nano-particle resulting solution with the metal nano-wire resulting solution comprises:
mixing the portion of the metal nano-particle resulting solution and the second capping agent with the second reductant to form a mixed solution;
putting the mixed solution in an opaque locking bottle;
performing a pre-heating treatment on the mixed solution in the opaque locking bottle to heat the mixed solution to a synthesis temperature; and
adding the second metal ionic compound into the mixed solution at the synthesis temperature to form the metal nano-wires by using the metal nano-particles as the seeds.

10. The method of claim 9, wherein the operation of mixing the portion of the metal nano-particle resulting solution and the second capping agent with the second reductant further comprises controlling a mixing temperature ranging from 10 degrees centigrade to 50 degrees centigrade.

11. The method of claim 9, wherein the synthesis temperature ranges from 70 degrees centigrade to 170 degrees centigrade.

12. The method of claim 1, wherein
each of the first metal ionic compound and the second metal ionic compound comprises at least one copper ionic compound;
each of the first capping agent and the second capping agent is an amine compound; and
each of the first reductant and the second reductant is an aldehyde compound.

13. The method of claim 12, wherein the amine compound is hexamethylene diamine, and the aldehyde compound is carbohydrate, vitamin C or hydrazine.

14. The method of claim 12, wherein the operation of preparing the metal nano-particle resulting solution comprises:
mixing the first metal ionic compound and the first capping agent to form a mixed solution using a solvent, wherein the solvent is distilled water;
putting the mixed solution in an opaque locking bottle;
performing a pre-heating treatment on the mixed solution in the opaque locking bottle; and
adding the first reductant into the mixed solution and the mixed solution is heated to a synthesis temperature to form the metal nano-particles.

15. The method of claim 14, wherein the operation of mixing the first metal ionic compound and the first capping agent using the solvent further comprises controlling a mixing temperature ranging from 10 degrees centigrade to 50 degrees centigrade.

16. The method of claim 14, wherein the synthesis temperature ranges from 70 degrees centigrade to 170 degrees centigrade.

17. The method of claim 12, wherein the operation of mixing the portion of the metal nano-particle resulting solution with the metal nano-wire resulting solution comprises:
mixing the second metal ionic compound and the second capping agent to form a mixed solution using a solvent, wherein the solvent is distilled water;
putting the mixed solution in an opaque locking bottle;
adding the portion of the metal nano-particle resulting solution into the mixed solution;
performing a pre-heating treatment on the mixed solution in the opaque locking bottle; and
adding the second reductant into the mixed solution and the mixed solution is heated to a synthesis temperature to form the metal nano-wires by using the metal nano-particles as the seeds.

18. The method of claim 17, wherein the operation of mixing the second metal ionic compound and the second capping agent using the solvent further comprises controlling a mixing temperature ranging from 10 degrees centigrade to 50 degrees centigrade.

19. The method of claim 17, wherein the synthesis temperature ranges from 70 degrees centigrade to 170 degrees centigrade.

20. The method of claim 1, between the operation of preparing the metal nano-particle resulting solution and the operation of performing the illumination treatment, the method further comprising storing the metal nano-particle resulting solution in an opaque environment with a storage temperature, wherein the storage temperature ranges from −20 degrees centigrade to 60 degrees centigrade.

21. The method of claim 1, wherein the operation of performing the illumination treatment comprises using a light source, and the light source has a wavelength ranging from 325 nm to 800 nm.

22. The method of claim 1, after the operation of mixing the portion of the metal nano-particle resulting solution with the metal nano-wire resulting solution, the method further comprising:
performing a first rinsing treatment on the metal nano-wires using acetone;
performing a second rinsing treatment on the metal nano-wires using distilled water; and
storing the metal nano-wires in distilled water.
